(19) United States
(12) Patent Application Publication
(10) Pub. No.: US 2011/0253523 A1
(43) Pub. Date: Oct. 20, 2011

(54) SPUTTERING APPARATUS AND METHOD

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 12/894,118

(22) Filed: Sep. 29, 2010

(30) Foreign Application Priority Data
Apr. 16, 2010 (TW) 99112089

(51) Int. Cl. C23C 14/34; C23C 14/50

(52) U.S. Cl. 204/192.1; 204/298.25; 901/31

(57) ABSTRACT

A sputtering apparatus includes a preheating chamber, a deposition chamber, a connection assembly connecting the preheating chamber to the deposition chamber, a first supporting assembly received in the preheating chamber, a second supporting assembly received in the deposition chamber, a number of posts capable of mounting on each of the first and second supporting assemblies, and a transferring robot arranged in the preheating chamber. The connection assembly includes a connection member defining a passage in communication with the preheating chamber and the deposition chamber and a partition plate moveably coupled to the connection member. The partition plate is configured for selectively closing or opening the passage. Each post fixes workpieces thereon. The transferring robot is configured for demounting the post from the two supporting assemblies, transferring the demounted post between the preheating chamber and the deposition chamber, and mounting the transferred post on the two supporting assemblies.

### BACKGROUND

1. Technical Field

The present disclosure relates to coating technologies and, particularly, to a sputtering apparatus and a sputtering method.

2. Description of Related Art

Generally, during sputtering process, a plurality of workpieces such as device housings are placed in an airtight chamber from which air is removed by a vacuum pump, after which an inert gas is introduced in the chamber to excite energized ions. The energized ions bombard a solid target material, vaporizing the same. The vaporized material is then deposited on the workpieces. After a set of workpieces is completely coated, the chamber is opened and the vacuum state is broken. The set of workpieces can be moved out of the chamber. Subsequent workpieces are then placed in the chamber for the next sputtering process. However, during the vacuum state break, the target material is easily oxidized by air or contaminated by dust, in which case coating efficiency and quality are influenced.

Therefore, what is needed is to provide a sputtering apparatus and method which can overcome the described limitations.

### BRIEF DESCRIPTION OF THE DRAWINGS

FIG. 1 is a schematic, isometric view of a sputtering apparatus including two rotating assemblies and a transferring robot, according to an exemplary embodiment, showing the transferring robot in a first state.

FIG. 2 is a schematic, isometric view of the rotating assembly with posts of FIG. 1

FIG. 3 is an enlarged view of a circled part III of the rotating assembly of FIG. 2.

FIG. 4 is an enlarged view of a circled part IV of the rotating assembly of FIG. 2.

FIG. 5 is similar to FIG. 1, but showing the transferring robot in a second state.

### DETAILED DESCRIPTION

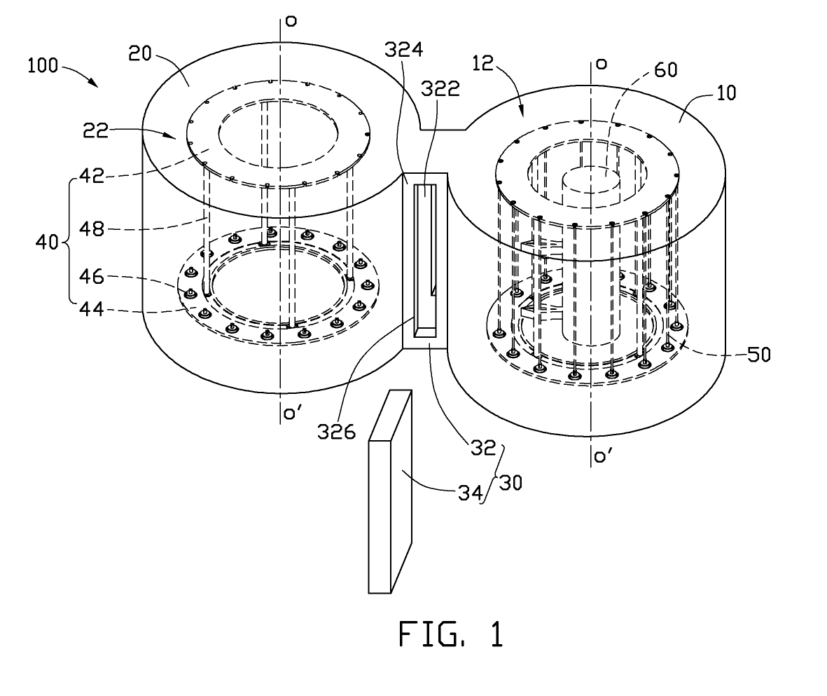

Referring to FIG. 1, a sputtering apparatus 100 for forming coatings on a plurality of workpieces (not shown), according to an exemplary embodiment, includes a preheating chamber 10, a deposition chamber 20, a connection assembly 30, two supporting assemblies 40, a number of posts 50, and a transferring robot 60.

The structure of the preheating chamber 10 is the same as that of the deposition chamber 20 in this embodiment. The preheating chamber 10 defines a preheating cavity 12. The deposition chamber 20 defines a deposition cavity 22. The connection assembly 30 includes a connection member 32 and a partition plate 34. The connection member 32 connects the preheating chamber 10 to the deposition chamber 20. The connection member 32 defines a passage 322. The passage 322 communicates with the preheating cavity 12 and the deposition cavity 22. The partition plate 34 is moveably coupled to the connection member 32 and configured for selectively closing or opening the passage 322. In this embodiment, the connection member 32 is substantially cuboid and includes four sidewalls. An opening 326 is defined in a sidewall 324 of the connection member 32. The partition plate 34 conforms to the opening 326 and the passage 322. The partition plate 34 extends through the opening 326 and is received in the passage 322 in an airtight manner. The passage 322 is sealed and divided into two sub-passages (not shown) by the partition plate 34. That is, the preheating cavity 12 is isolated from the deposition chamber 20 by the partition plate 34.

The two supporting assemblies 40 have the same structure. One supporting assembly 40 (the first supporting assembly) is received in the preheating cavity 12, and the other supporting assembly 40 (the second supporting assembly) is received in the deposition cavity 22. Each supporting assembly 40 defines a central axis OO′ thereof. The supporting assembly 40 is rotatable about the central axis OO′.

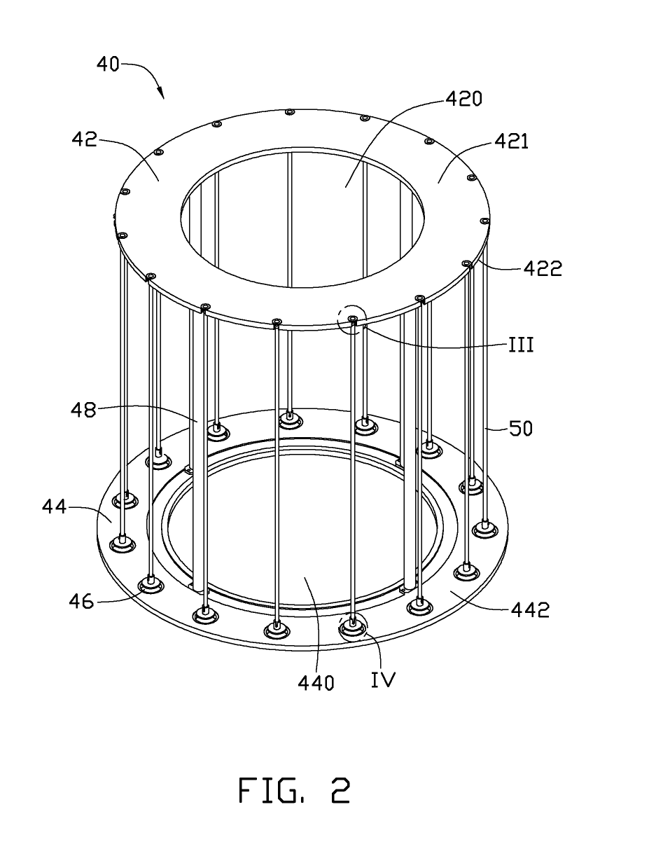

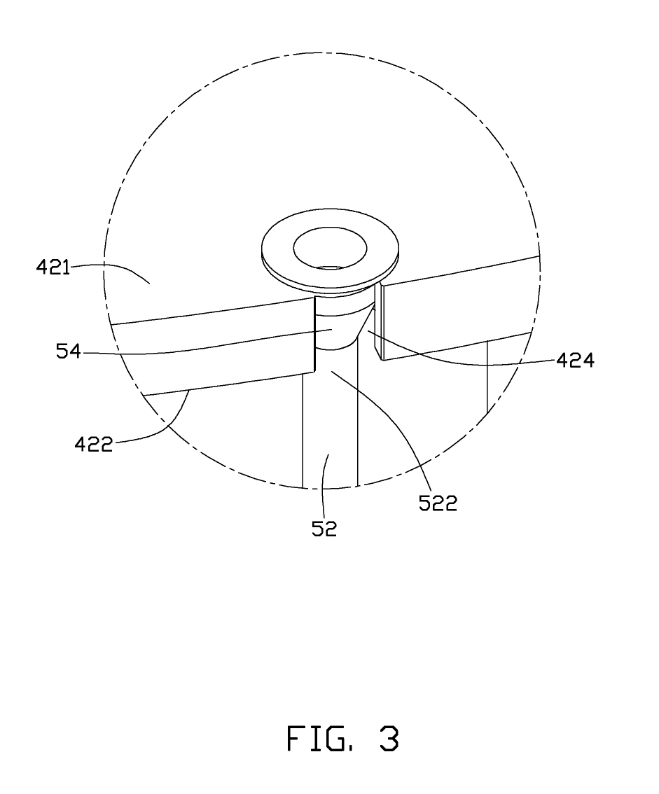

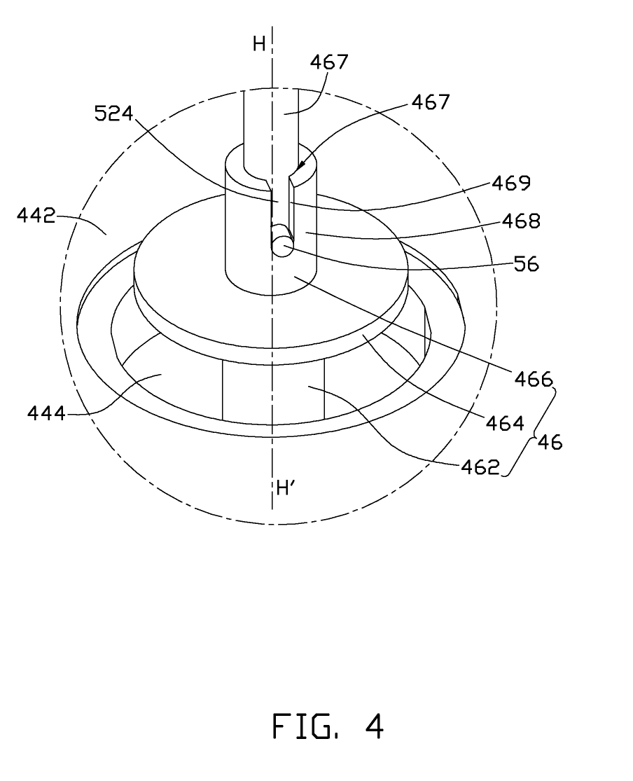

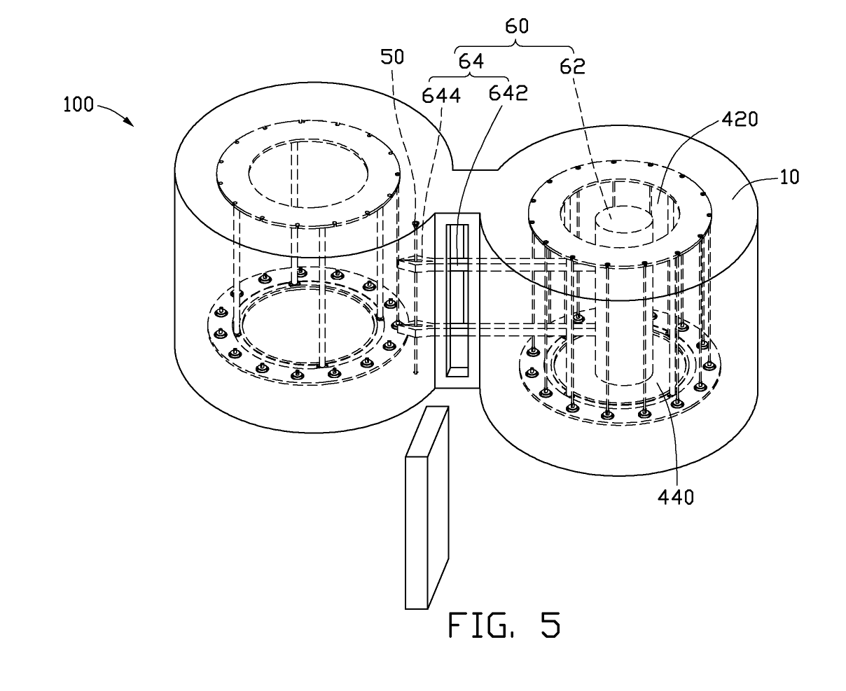

Referring to FIGS. 2-5, the supporting assembly 40 includes an upper base 42, a lower base 44, a number of seat members 46, and four connecting posts 48.

The upper base 42 is an annular planar plate and defines an upper through hole 420 at a center thereof. The upper base 42 includes a first surface 421 and a second surface 422. The first surface 421 and the second surface 422 are at opposite sides of the upper base 42. A number of cutouts 424 through the first surface 421 and the second surface 422 are defined on a peripheral edge of the upper base 42 opening toward a direction away from the central axis OO′. The cutouts 424 substantially taper away from the upper through hole 420. The diameter of each cutout 424 decreases from the first surface 421 to the second surface 422. In this embodiment, the cutouts 424 are equidistant around the central axis OO′.

The lower base 44 is an annular planar plate and defines a lower through hole 440 aligned with the upper through hole 420. The lower base 44 includes a third surface 442 opposite to the second surface 422. A plurality of first receiving holes 444 is defined in the third surface 442 aligned with the cutouts 424 and corresponding to the seat members 46.

Each seat member 46 is rotatably received in a corresponding first receiving hole 444. Each seat member 46 includes a supporting post 462, a supporting base 464, and a cylindrical engaging post 466. The supporting post 462 is received in a corresponding first receiving hole 444. The supporting post 462 and the engaging post 466 are aligned with each other and extend from opposite sides of the supporting base 464. Each seat member 46 is rotatable about a longitudinal axis HH′ of the supporting post 462. The engaging post 466 includes a second receiving hole 467, a sidewall 468 surrounding the second receiving hole 467, and a slot 469 defined in the sidewall 468.

The four connecting posts 48 are interconnected between the second surface 422 and the third surface 442. The four connecting posts 48 are spaced from the cutouts 424 and the first receiving holes 444. In this embodiment, the four connecting posts 48 are equidistant around the central axis OO′.

The posts 50 are capable of mounting on the supporting assembly 40 and are configured for fixing the workpieces thereon. Each post 50 includes a rod body portion 52, an engaging portion 54, and a protrusion 56. The rod body portion 52 is a cylinder and includes a first end 522 and a second end 524 conforming to the second receiving hole 467. The first end 522 and the second end 524 are at opposite sides of the rod body portion 52. The engaging portion 54 extends from the first end 522 along the longitudinal axis of the rod body portion 52. The engaging portion 54 has a greater size than that of the rod body portion 52. The diameter of the rod body portion 52 is less than that of the least diameter of the cutout 424. The engaging portion 54 has a tapered section conforming to the cutout 424. The protrusion 56 extends radially from the second end 524 conforming to the slot 469.

When a post 50 is mounted on the supporting assembly 40, the post 50 is lifted to raise the engaging portion 54 above the first surface 421, elevate the second end 524 above the engaging post 466, and align the protrusion 56 with the slot 469. The post 50 is then moved toward the third surface 442 until the engaging portion 54 engages in the cutout 424 and the second end 524 is received in the second receiving hole 467 and the protrusion 56 engages in the slot 469. Thus, the engaging portion 54 is positioned by the cutout 424 and the second end 524 is positioned in the seat member 46 via the protrusion 56 being blocked by the slot 469. As a result, the post 50 can rotate about the longitudinal axis HH′ with the rotation of the seat member 46. When the post 50 is demounted from the supporting assembly 40, the post 50 is lifted to raise the engaging portion 54 above the first surface 421 and to elevate the second end 524 above engaging post 466. The post 50 is then radially moved away from the central axis OO′ to separate from the supporting assembly 40.

The transferring robot 60 includes a receiving case 62, a driving member (not shown), and two manipulators 64. The receiving case 62 is positioned in the preheating chamber 10 and passes through the upper through hole 420 and the lower through hole 440. The driving member is received in the receiving case 62. Each manipulator 64 includes an arm 642 and a clamp 644 arranged on the arm 642. The arms 642 are received in the receiving case 62, and the clamps 644 exposed at the receiving case 62. The driving member is mechanically and electrically connected to the manipulators 64. When the driving member is implemented, the arms 642 protrude out of or retract into the receiving case 62. The arms 642 can also move downward or upward and the clamps 644 grip a post 50. In this embodiment, the arms 642 are extendable or retractable along a direction perpendicular to the central axis OO′, the arms 642 are moveable along the central axis OO′ direction. The manipulators 64 are configured for demounting the post 50 from the supporting assembly 40 in the preheating chamber 10, transferring the demounted post 50 from the preheating chamber 10 to the deposition chamber 20, mounting the transferred post 50 on the supporting assembly 40 in the deposition chamber 20, demounting the post 50 from the supporting assembly 40 in the deposition chamber 20, transferring the demounted post 50 from the deposition chamber 20 to the preheating chamber 10, and mounting the transferred post 50 on the supporting assembly 40 in the preheating chamber 10.

A sputtering method for forming coatings on a plurality of workpieces (not shown) can be implemented by, for example, the sputtering apparatus 100 and includes the following steps. Workpieces are placed in the preheating chamber 10. In particular, after the workpieces are fixed on the posts 50, the posts 50 are mounted on the supporting assembly 40 in the preheating chamber 10. Each post 50 is manually or automatically lifted to elevate the engaging portion 54 above the first surface 421, raise the second end 524 above the engaging post 466, and align the protrusion 56 with the slot 469. The post 50 is then moved toward the third surface 442 until the engaging portion 54 engages in the cutout 424 and the second end 524 is received in the second receiving hole 467 and the protrusion 56 engages in the slot 469.

The preheating chamber 10 is evacuated. In particular, air from the preheating chamber 10 is evacuated by a vacuum pump (not shown).

The preheating chamber 10 is heated. In particular, the workpieces therein are preheated by a heater (not shown). In this step, the supporting assembly 40 in the preheating chamber 10 rotates about the central axis OO′ and the posts 50 rotate about the longitudinal axis HH′ with the rotation of the seat member 46.

The posts 50 are transferred from the preheating chamber 10 to the deposition chamber 20 through the passage 322 and mounted on the supporting assembly 40 in the deposition chamber 20. In particular, the clamps 644 clamp a post 50 in the preheating chamber 10. The arms 642 moves upward along the central axis OO′ direction until the engaging portion 54 is above the first surface 421 and the second end 524 is above the engaging post 466. The arms 642 protrude out of the preheating chamber 10 and enter the deposition chamber 20 to correspond to the supporting assembly 40 therein. The arms 642 finally moves downward along the central axis OO′ direction until the engaging portion 54 engages in the cutout 424 and the second end 524 is received in the second receiving hole 467 and the protrusion 56 engages in the slot 469. The clamps 644 release the post 50 and the arms 642 retract into the receiving case 62 for transferring the next post 50. Operations are thus repeated until all posts 50 are transferred from the preheating chamber 10 to the deposition chamber 20.

The passage 322 is closed to isolate the preheating cavity 12 from the deposition cavity 22. In particular, the partition plate 34 extends through the opening 326 and is received in the passage 322 in an airtight manner so that the passage 322 is sealed and is divided into two sub-passages (not shown) by the partition plate 34.

The deposition chamber 20 is evacuated. In particular, air is evacuated from the deposition chamber 20 by a vacuum pump (not shown).

The workpieces are coated in the deposition chamber 20 using a sputtering process. In particular, an inert gas is introduced in the deposition chamber 20 to excite energized ions. The energized ions bombard a solid target material (not shown) to vaporize the material. The vaporized material is then deposited on the workpieces.

The passage 322 is opened. In particular, the partition plate 34 is removed from the the passage 322.

The posts 50 with coated workpieces are transferred from the deposition chamber 20 to the preheating chamber 10 and mounted on the supporting assembly 40 in the preheating chamber 10.

The passage 322 is closed to maintain the deposition chamber 20 in a vacuum state.

The preheating chamber 10 is opened and the coated workpieces are removed therefrom.

The steps can be repeated to process subsequent workpieces. During the method as disclosed, the deposition chamber 20 maintains a vacuum state so the target material is not oxidized nor is contaminated by dust. This increases coating efficiency and quality.

It is to be understood, however, that even though numerous characteristics and advantages of the present embodiments have been set forth in the foregoing description, together with details of the structures and functions of the embodiments, the disclosure is illustrative only, and changes may be made in details, especially in matters of shape, size, and arrangement of parts within the principles of the invention to the full extent indicated by the broad general meaning of the terms in which the appended claims are expressed.

What is claimed is:

1. A sputtering apparatus comprising:
a preheating chamber;
a deposition chamber;
a connection assembly connecting the preheating chamber to the deposition chamber, the connection assembly comprising a connection member defining a passage in communication with the preheating chamber and the deposition chamber and a partition plate moveably coupled to the connection member, the partition plate configured for selectively closing or opening the passage;
a first supporting assembly received in the preheating chamber;
a second supporting assembly received in the deposition chamber;
a plurality of posts capable of mounting on each of the first and second supporting assemblies, each post configured for fixing workpieces thereon, and
a transferring robot arranged in the preheating chamber, the transferring robot configured for demounting the post from the first supporting assembly, transferring the demounted post from the preheating chamber to the deposition chamber, mounting the transferred post on the second supporting assembly, demounting the post from the second supporting assembly, transferring the demounted post from the deposition chamber to the preheating chamber, and mounting the transferred post on the first supporting assembly.

2. The sputtering apparatus as claimed in claim 1, wherein the connection member defines an opening in communication with the passage, and the partition plate passable through the opening.

3. The sputtering apparatus as claimed in claim 2, wherein each of the first and second supporting assemblies is rotatable about a central axis thereof.

4. The sputtering apparatus as claimed in claim 3, wherein each of the first and second supporting assemblies comprises an upper base, a lower base, a plurality of seat members, and at least two connecting posts, the upper base is opposite to the lower base, the seat members are mounted to the lower base facing the upper base, the connecting posts are interconnected between the upper base and the lower base.

5. The sputtering apparatus as claimed in claim 4, wherein the upper base comprises a plurality of cutouts defined in a peripheral edge thereof opening toward a direction away from the central axis, the lower base defines a plurality of first receiving holes aligned with the cutouts, the seat members are rotatably received in the corresponding first receiving holes, the cutouts and the seat members configured for engaging with the respective posts.

6. The sputtering apparatus as claimed in claim 5, wherein each seat member comprises a supporting post received in the corresponding first receiving hole, a supporting base, and a cylindrical engaging post, the supporting post and the engaging post are aligned with each other and extend from opposite sides of the supporting base, each seat member being rotatable about a longitudinal axis of the supporting post, each post extending through the respective cutout and jointly rotatable with the rotation of the corresponding seat member.

7. The sputtering apparatus as claimed in claim 6, wherein each engaging post comprises a second receiving hole, a sidewall surrounding the second receiving hole, and a slot defined in the sidewall, and each post comprises a rod body portion, an engaging portion having a greater size than that of the rod body portion, and a protrusion extending from the rod body portion and engaged in the slot, the rod body portion comprises a first end and an opposing second end receivingly engaged in the second receiving hole, the engaging portion engaged in the cutout, the protrusion extending from the second receiving hole to the slot.

8. The sputtering apparatus as claimed in claim 7, wherein the upper base is an annular planar plate and defines an upper through hole at a center thereof, the lower base is an annular planar plate and defines a lower through hole aligned with the upper through hole, and the transferring robot passes through the upper through hole and the lower through hole.

9. The sputtering apparatus as claimed in claim 8, wherein the transferring robot comprises a receiving case, a driving member, and two manipulators, the driving member is received in the receiving case and is mechanically and electrically connected to the manipulators, the manipulators are configured for demounting the post from the first supporting assembly, transferring the demounted post from the preheating chamber to the deposition chamber, mounting the transferred post on the second supporting assembly, demounting the post from the second supporting assembly, transferring the demounted post from the deposition chamber to the preheating chamber, and mounting the transferred post on the first supporting assembly.

10. The sputtering apparatus as claimed in claim 9, wherein each manipulator comprises an arm and a clamp arranged on the arm and configured for clamping the post, the arm is received in the receiving case, the clamp exposed at the receiving case, the arm being extendable or retractable along a direction perpendicular to the central axis, the arm being movable along the central axis direction.

11. A sputtering method comprising:
providing a sputtering apparatus comprising a preheating chamber, a passage, and a deposition chamber in communication with the preheating chamber via the passage;
placing workpieces in the preheating chamber;
evacuating the preheating chamber;
heating the preheating chamber;
transferring the workpieces from the preheating chamber to a deposition chamber through the passage;
closing the passage to isolate the preheating chamber from the deposition chamber;
evacuating the deposition chamber;
coating the workpieces in the deposition chamber using a sputtering process;
opening the passage;
transferring the coated workpieces from the deposition chamber to the preheating chamber;
closing the passage and maintaining the deposition chamber in a vacuum state; and
removing the coated workpieces from the preheating chamber.
